(19) United States
(12) Patent Application Publication
(10) Pub. No.: US 2026/0029721 A1
(43) Pub. Date: Jan. 29, 2026

(54) METHOD OF FABRICATING SEMICONDUCTOR PACKAGE

(71) Applicant: SAMSUNG ELECTRONICS CO., LTD., Suwon-si (KR)

(72) Inventors: Seyeong Seok, Suwon-si (KR); Dongwoo Kim, Suwon-si (KR); Daseul Lee, Suwon-si (KR); Jonghyeon Chang, Suwon-si (KR)

(73) Assignee: SAMSUNG ELECTRONICS CO., LTD., Suwon-si (KR)

(21) Appl. No.: 19/184,264

(22) Filed: Apr. 21, 2025

(30) Foreign Application Priority Data
Jul. 29, 2024 (KR) 10-2024-0100172

(51) Int. Cl. H01L 23/00; G03F 7/16; H01L 21/768

(52) U.S. Cl. CPC H01L 24/03; G03F 7/168; H01L 21/76898; H01L 2224/03002; H01L 2224/0362; H01L 2224/0391

(57) ABSTRACT

A method of manufacturing a semiconductor package includes providing a wafer substrate including a first a chip area and an edge area; forming first and second conductive layers on the wafer substrate; forming a photoresist pattern, including openings, on the second conductive layer, wherein the photoresist pattern includes a first photoresist pattern on the chip area and a second photoresist pattern on the edge area; forming conductive patterns within the openings; removing the first photoresist pattern from the photoresist pattern, and portions of the first and second conductive layers overlapping with the first photoresist pattern; removing the second photoresist pattern from the photoresist pattern, and a portion of the second conductive layer overlapping the second photoresist pattern, such that a portion of the first conductive layer on the edge area is exposed; and forming a protective film such that the protective film is on the conductive patterns.

### CROSS-REFERENCE TO RELATED APPLICATION(S)

This application claims priority under 35 USC 119(a) to Korean Patent Application No. 10-2024-0100172, filed on Jul. 29, 2024, in the Korean Intellectual Property Office, the entire disclosure of which is incorporated herein by reference for all purposes.

### BACKGROUND

The present disclosure relates to a method of fabricating a semiconductor package, and more particularly, to a method of fabricating a semiconductor package including a wafer substrate on which semiconductor chips are stacked.

A plurality of semiconductor chips may be manufactured by performing various semiconductor processes on a semiconductor wafer substrate. After a process of forming pads on a back surface of the semiconductor wafer substrate, a protective film may be formed to protect the back surface of the semiconductor wafer substrate prior to a dicing process for the semiconductor wafer substrate. In addition, after the operation of forming the protective film, a carrier substrate formed on a front surface of the semiconductor wafer substrate may be removed. During the process of removing the carrier substrate, the protective film may be lifted or the adhesive strength of the protective film may be reduced due to a difference in a peeling force. Due to such problems, particles may be introduced onto the semiconductor wafer substrate or cracks may be generated in the semiconductor wafer substrate, which may reduce a production yield of the plurality of semiconductor chips at the wafer level and deteriorate reliability.

### SUMMARY

Example embodiments provide a method of manufacturing a semiconductor package which may have improved process yield and reliability at a wafer substrate level.

According to an aspect of the disclosure, a method of manufacturing a semiconductor package includes: providing a wafer substrate including a first surface, a second surface opposite to the first surface, a chip area, and an edge area surrounding the chip area; sequentially forming a first conductive layer and a second conductive layer on the second surface of the wafer substrate; forming a photoresist pattern, including openings exposing the second conductive layer, on the second conductive layer, wherein the photoresist pattern includes a first photoresist pattern on the chip area and a second photoresist pattern on the edge area; forming conductive patterns within the openings; removing the first photoresist pattern on the chip area from the photoresist pattern, and portions of the first conductive layer and the second conductive layer overlapping with the first photoresist pattern; removing the second photoresist pattern on the edge area from the photoresist pattern, and a first portion of the second conductive layer overlapping the second photoresist pattern, such that at least a first portion of the first conductive layer on the edge area is exposed; and forming a protective film on the second surface such that the protective film is on the conductive patterns.

According to an aspect of the disclosure, a method of manufacturing a semiconductor package includes: preparing a wafer substrate including a first surface, a second surface opposite to the first surface, a chip area, and an edge area surrounding the chip area; forming through-electrodes penetrating the wafer substrate; forming, on the first surface of the wafer substrate, connection bumps connected to the through-electrodes; sequentially forming an adhesive layer and a carrier substrate on the first surface of the wafer substrate such that the adhesive layer and the carrier substrate are on the connection bumps; sequentially forming a first conductive layer and a second conductive layer on the second surface of the wafer substrate; forming a photoresist pattern, including openings exposing the second conductive layer and overlapping with the through-electrodes, on the second conductive layer, wherein the photoresist pattern includes a first photoresist pattern on the chip area and a second photoresist pattern on the edge area; forming conductive patterns within the openings; forming chip pads by removing the first photoresist pattern on the chip area from the photoresist pattern, and a first portion of the first conductive layer overlapping the first photoresist pattern and the second conductive layer; forming dummy pads by removing the second photoresist pattern of the edge area from the photoresist pattern, and a first portion of the second conductive layer overlapping the second photoresist pattern; and forming a protective film on the second surface of the wafer substrate such that the protective film is on the chip pads and the dummy pads.

According to an aspect of the disclosure, a method of manufacturing a semiconductor package includes: providing a wafer substrate including a first surface, a second surface opposite to the first surface, a chip area, and an edge area surrounding the chip area; forming connection structures on the first surface of the wafer substrate; sequentially forming an adhesive layer and a carrier substrate on the first surface of the wafer substrate such that the adhesive layer and the carrier substrate are on the connection structures; sequentially forming a first conductive layer and a second conductive layer on the second surface of the wafer substrate; forming a photoresist pattern, including openings exposing the second conductive layer, on the second conductive layer, wherein the photoresist pattern includes a first photoresist pattern on the chip area and a second photoresist pattern on the edge area; forming conductive patterns within the openings; sequentially removing the first photoresist pattern on the chip area from the photoresist pattern and portions of the first conductive layer and the second conductive layer overlapping the first photoresist pattern; sequentially removing the second photoresist pattern on the edge area from the photoresist pattern and a first portion of the second conductive layer overlapping the second photoresist pattern; and forming a protective film on the second surface of the wafer substrate such that the protective film is on the conductive patterns, wherein the adhesive layer has first peel strength with respect to the wafer substrate, and wherein the protective film has second peel strength, greater than the first peel strength, with respect to a first portion of the first conductive layer on the edge area.

### BRIEF DESCRIPTION OF DRAWINGS

The above and other aspects, features, and advantages of the disclosure will be more clearly understood from the following detailed description, taken in conjunction with the accompanying drawings, in which:

FIG. 1A is a plan view of a wafer substrate illustrating a wafer-level semiconductor package according to example embodiments;

FIG. 1B is a cross-sectional view illustrating a wafer-level semiconductor package diced along a scribe line of the wafer substrate of FIG. 1A;

FIGS. 2A and 2B are drawings illustrating a wafer substrate supporting process of a semiconductor package in a method of manufacturing a semiconductor package according to an example embodiment;

FIGS. 3A to 3T are drawings illustrating an example embodiment of a method of manufacturing a semiconductor package to illustrate a wafer substrate supporting process of the semiconductor package of FIGS. 2A and 2B.

FIGS. 4A and 4B are drawings illustrating a wafer substrate supporting process of a semiconductor package in a method of manufacturing a semiconductor package according to another embodiment;

FIGS. 5A to 5H are drawings illustrating an example embodiment of a method of manufacturing a semiconductor package to illustrate a wafer substrate supporting process of the semiconductor package of FIGS. 4A and 4B;

FIGS. 6A and 6B are drawings illustrating a wafer substrate supporting process of a semiconductor package in a method of manufacturing a semiconductor package according to another embodiment; and

FIGS. 7A to 7P are drawings illustrating an example embodiment of a method of manufacturing a semiconductor package to illustrate a wafer substrate supporting process of the semiconductor package of FIGS. 6A and 6B.

### DETAILED DESCRIPTION

Hereinafter, with reference to the attached drawings, non-limiting example embodiments of the disclosure will be described in more detail. The same reference numerals are used for the same components in the drawings, and duplicate descriptions of the same components may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

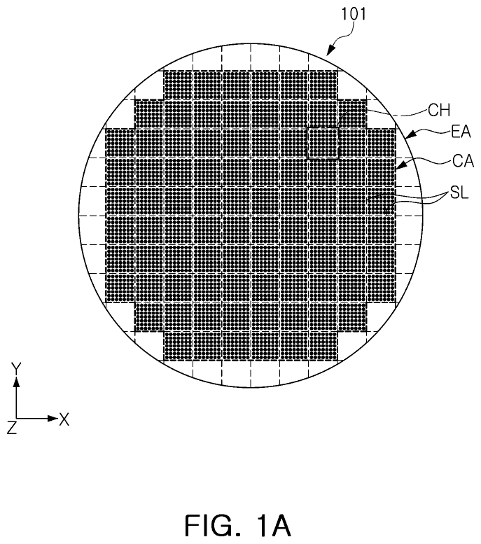

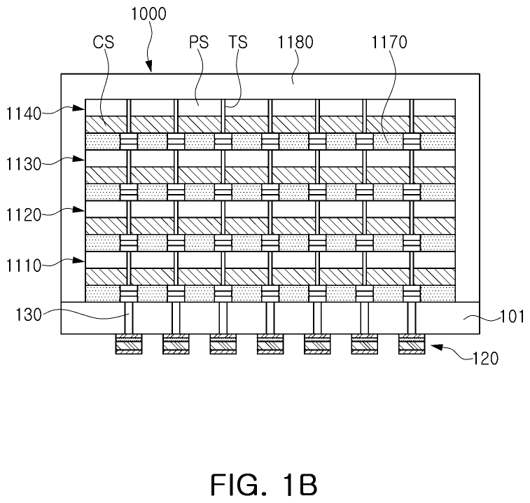

FIG. 1A is a plan view of a wafer substrate illustrating a wafer-level semiconductor package according to example embodiments. FIG. 1B is a cross-sectional view illustrating a wafer-level semiconductor package diced along a scribe line of the wafer substrate of FIG. 1A.

Referring to FIGS. 1A and 1B, a wafer-level semiconductor package 1000 may include a wafer substrate 101, a plurality of semiconductor chips 1110, 1120, 1130 and 1140 on the wafer substrate 101, adhesive material layers 1170 between the plurality of semiconductor chips 1110, 1120, 1130 and 1140, and a mold layer 1180. The wafer-level semiconductor package 1000 may further include a plurality of pads 120 disposed on the lower surface of the wafer substrate 101 and a through-electrode 130 penetrating the wafer substrate 101.

The wafer substrate 101 may be a circular wafer. The wafer substrate 101 may be a silicon wafer, but is not limited thereto. For example, the wafer substrate 101 may include a ceramic substrate, a printed circuit board (PCB), an organic substrate, and/or an interposer substrate. In an example, the wafer substrate 101 may include a chip area CA on which an integrated circuit is formed, and an edge area EA on which the integrated circuit is not formed and which surrounds the chip area CA. The chip area CA of the wafer substrate 101 may include a plurality of package areas CH divided by a scribe line SL. The plurality of package areas CH may be disposed in a grid shape along the scribe line SL. The plurality of package areas CH may respectively be aligned in a first direction (X-direction) and a second direction (Y-direction).

A wafer substrate 101 may be provided on which a plurality of semiconductor chips 1110, 1120, 1130 and 1140 are stacked on an upper surface thereof, thereby configuring a semiconductor package.

A plurality of semiconductor chips 1110, 1120, 1130 and 1140 may be stacked vertically on the wafer substrate 101. The plurality of semiconductor chips 1110, 1120, 1130 and 1140 may include first to fourth semiconductor chips (e.g., semiconductor chips 1110 to 1140). In an example, the semiconductor chips 1110 to 1140 may be sequentially stacked on the wafer substrate 101 in the third direction (Z-direction).

The plurality of semiconductor chips 1110, 1120, 1130 and 1140 are illustrated as including four semiconductor chips, but are not limited thereto, and for example, may include four or more semiconductor chips. The plurality of semiconductor chips 1110, 1120, 1130 and 1140 are illustrated as having the same shape, but are not limited thereto. For example, the plurality of semiconductor chips 1110, 1120, 1130 and 1140 may include different types of semiconductor chips or different shapes of semiconductor chips. In an example, the plurality of semiconductor chips 1110, 1120, 1130 and 1140 may be memory semiconductor chips such as dynamic random-access memories (DRAMs).

The plurality of semiconductor chips 1110, 1120, 1130 and 1140 may each include a first chip structure CS, a second chip structure PS disposed on the first chip structure CS, and a connection structure TS penetrating the first chip structure CS and the second chip structure PS.

The adhesive material layers 1170 may surround a space between the first semiconductor chip 1110 and the wafer substrate 101, and a space between the plurality of semiconductor chips 1110, 1120, 1130 and 1140. In an example, the adhesive material layers 1170 may include an epoxy material. For example, the adhesive material layers 1170 may be a Non-Conductive Film (NCF), but the example embodiment is not limited to such a material.

In an example embodiment, the mold layer 1180 is disposed to cover the plurality of semiconductor chips 1110, 1120, 1130 and 1140 and the adhesive material layers 1170 to protect the plurality of semiconductor chips 1110, 1120, 1130 and 1140 and the adhesive material layers 1170 from the external environment. In an example, the mold layer 1180 may include an insulating material including a resin material such as an epoxy molding compound (EMC).

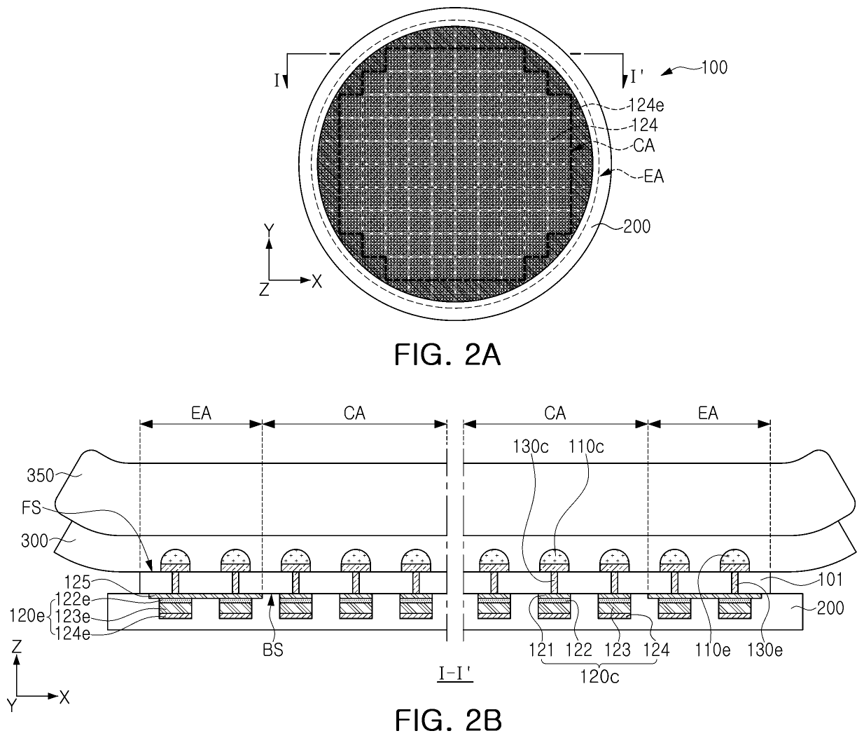

FIGS. 2A and 2B are drawings illustrating a wafer substrate supporting process of a semiconductor package in a method of manufacturing a semiconductor package according to an example embodiment. FIGS. 2A and 2B illustrate a first plan view and a cross-sectional view along the line I-I′ of the first plan view, respectively, which illustrate an example embodiment of a wafer substrate supporting process operation of a semiconductor package.

Referring to FIGS. 2A and 2B, the wafer substrate supporting process 100 may refer to a process of forming a carrier substrate 350 covering a front surface FS of the wafer substrate 101 to protect the front surface FS of the wafer substrate 101 prior to a process of forming a plurality of pads (e.g., chip pads 120c and dummy pads 120e) on a back surface BS of the wafer substrate 101, and a process of forming a protective film 200 covering the back surface BS of the wafer substrate 101 to protect the back surface BS of the wafer substrate 101 after the process of forming a plurality of pads (e.g., the chip pads 120c and the dummy pads 120e) on the back surface of the wafer substrate 101 and prior to a dicing process for the wafer substrate 101. The carrier substrate 350 and the protective film 200 may protect the wafer substrate 101 from contamination or physical/chemical damage due to contact with the external environment, and the protective film 200 may prevent cracks or the like from occurring during the dicing process.

The carrier substrate 350 may be attached to the front surface FS of the wafer substrate 101 by an adhesive layer 300. The wafer substrate 101 and the adhesive layer 300 may be removed prior to the dicing process for the wafer substrate 101.

The wafer substrate 101 may include a front surface FS on which a plurality of connection bumps 110c and dummy connection bumps 110e are formed, and a back surface BS facing opposite of front surface FS on which the plurality of pads (e.g., the chip pads 120c and the dummy pads 120e) are formed.

The front surface FS of the wafer substrate 101 may be a surface on which semiconductor chips connected to the connection bumps 110c and the dummy connection bumps 110e disposed on the upper surface of the integrated circuit are bonded. In this document, the front surface FS may be referred to as the first surface, and the back surface BS may be referred to as the second surface.

The wafer substrate 101 may include a chip area CA in which a plurality of semiconductor package areas (e.g., a plurality of package areas CH) are formed, and an edge area EA that surrounds the chip area CA and is an edge area of the wafer substrate 101.

The connection bumps 110c may be provided and/or formed on the chip area CA of the wafer substrate 101, and dummy connection bumps 110e may be provided and/or formed on the edge area EA of the wafer substrate 101. The connection bumps 110c on the chip area CA of the wafer substrate 101 may be connected to a plurality of semiconductor chips (e.g., a plurality of semiconductor chips 1110, 1120, 1130 and 1140 of FIG. 1B), and the dummy connection bumps 110e on the edge area EA of the wafer substrate 101 may not be connected to the plurality of semiconductor chips. The connection bumps 110c may be referred to as connection structures in this document. The connection bumps 110c are not limited to bumps, and may include solder balls, pin grid arrays, ball grid arrays, and micro pillar grid arrays.

The plurality of connection bumps 110c and dummy connection bumps 110e may include tin (Sn) or an alloy (e.g., Sn—Ag—Cu) including tin (Sn).

The chip pads 120c may be provided and/or formed on the chip area CA of the wafer substrate 101. The dummy pads 120e may be provided and/or formed on the edge area EA of the wafer substrate 101. In an example, the chip pads 120c may overlap with the connection bumps 110c in the vertical direction (Z-direction). The dummy pads 120e may overlap with the dummy connection bumps 110e in the vertical direction (Z-direction).

Through-electrode 130c may be provided and/or formed to penetrate the wafer substrate 101 in the chip area CA in a vertical direction (Z-direction). Dummy through-electrode 130e may be provided and/or formed to penetrate the wafer substrate 101 in the edge area EA in a vertical direction (Z-direction). The through-electrodes 130c may electrically connect the connection bumps 110c and the chip pads 120c. The dummy through-electrodes 130e may electrically connect the dummy connection bumps 110e and the dummy pads 120e.

The chip pads 120c disposed on the chip area CA may respectively contact the lower surface of the wafer substrate 101. The dummy pads 120e disposed on the edge area EA may respectively contact the lower surface of a dummy conductive layer 125.

The dummy conductive layer 125 may be disposed on the lower surface of the wafer substrate 101 in the edge area EA, and at least a portion of the dummy conductive layer 125 may be exposed at the lower surface of the wafer substrate 101. The dummy conductive layer 125 may include a first portion between the dummy pads 120e and a second portion overlapping with the dummy pads 120e of the edge area EA. The dummy conductive layer 125 may cover an area corresponding to the edge area EA on the lower surface of the wafer substrate 101. In the edge area EA, the edge of the lower surface of the wafer substrate 101 may be exposed from the dummy conductive layer 125.

Each of the chip pads 120c may include first to fourth metal layers that are sequentially stacked on the lower surface of the wafer substrate 101. The first to fourth metal layers may include a first metal layer 121 that contacts the lower surface of the wafer substrate 101, a second metal layer 122 that is disposed on the lower surface of the first metal layer 121, a third metal layer (e.g., first conductive pattern 123) that is disposed on the lower surface of the second metal layer 122, and a fourth metal layer (e.g., second conductive pattern 124) that is disposed on the lower surface of the third metal layer (e.g., first conductive pattern 123). The first to fourth metal layers may respectively include different metal materials from each other. For example, the first metal layer 121 may include titanium (Ti), the second metal layer 122 may include copper (Cu), the third metal layer (e.g., first conductive pattern 123) may include nickel (Ni), and the fourth metal layer (e.g., second conductive pattern 124) may include gold (Au). The fourth metal layer (e.g., second conductive pattern 124) may function as a barrier film for the third metal layer (e.g., first conductive pattern 123).

The dummy pads 120e may be respectively disposed on the lower surface of the dummy conductive layer 125 disposed on the lower surface of the wafer substrate 101. The dummy pads 120e disposed on the lower surface of the wafer substrate 101 in the edge area EA may be on a same one of the dummy conductive layers 125.

The dummy pads 120e may include first to third dummy electrode layers. The first to third dummy electrode layers may include a first dummy electrode layer 122e that is in contact with the lower surface of the dummy conductive layer 125, a second dummy electrode layer (e.g., first conductive pattern 123e) that is disposed on the lower surface of the first dummy electrode layer 122e, and a third dummy electrode layer (e.g., second conductive pattern 124e) that is disposed on the lower surface of the second dummy electrode layer (e.g., first conductive pattern 123e).

The dummy conductive layer 125 may include the same metal material as the first metal layer 121. For example, the dummy conductive layer 125 and the first metal layer 121 may include titanium (Ti). The dummy conductive layer 125 and the first metal layer 121 may be in contact with the lower surface of the wafer substrate 101 and may be disposed at the same level as each other. In an example, the lower surface of the dummy conductive layer 125 may be disposed at the same level as the lower surface of the first metal layer 121 of the chip pads 120c.

The first dummy electrode layer 122e may include the same metal material as the second metal layer 122. For example, the first dummy electrode layer 122e and the second metal layer 122 may include copper (Cu). The first dummy electrode layer 122e may be disposed at the same level as the second metal layer 122. In an example, the lower surface of the first dummy electrode layer 122e may be disposed at the same level as the lower surface of the second metal layer 122.

The second dummy electrode layer (e.g., first conductive pattern 123e) may include the same metal material as the third metal layer (e.g., first conductive pattern 123). For example, the second dummy electrode layer (e.g., first conductive pattern 123e) and the third metal layer (e.g., first conductive pattern 123) may include nickel (Ni). The second dummy electrode layer (e.g., first conductive pattern 123e) may be disposed at the same level as the third metal layer (e.g., first conductive pattern 123). In an example, the lower surface of the second dummy electrode layer (e.g., first conductive pattern 123e) may be disposed at the same level as the lower surface of the third metal layer (e.g., first conductive pattern 123).

The third dummy electrode layer (e.g., second conductive pattern 124e) may include the same metal material as the fourth metal layer (e.g., second conductive pattern 124). For example, the third dummy electrode layer (e.g., second conductive pattern 124e) and the fourth metal layer (e.g., second conductive pattern 124) may include gold (Au). The third dummy electrode layer (e.g., second conductive pattern 124e) and the fourth metal layer (e.g., second conductive pattern 124) may be disposed at the same level as each other. In an example, the lower surface of the dummy electrode layer (e.g., second conductive pattern 124e) may be placed at the same level as the lower surface of the fourth metal layer (e.g., second conductive pattern 124).

The carrier substrate 350 may be attached to the front surface FS of the wafer substrate 101 by the adhesive layer 300. The carrier substrate 350 may be a temporary carrier substrate for protecting the front surface FS of the wafer substrate 101 in a subsequent process for forming a plurality of connection bumps 110c and dummy connection bumps 110e on the front surface FS of the wafer substrate 101.

The carrier substrate 350 may cover the front surface FS of the wafer substrate 101 with the adhesive layer 300 therebetween. The carrier substrate 350 may include, but is not limited to, a sapphire or glass substrate and may be formed of the same material as the wafer substrate 101. The adhesive layer 300 may be formed of an adhesive material including a polymer or resin. The adhesive layer 300 may be in the form of a tape. The height of the carrier substrate 350 in the vertical direction (Z-direction) may be higher than the height of the wafer substrate 101 in the vertical direction (Z-direction).

After forming a plurality of pads (e.g., the chip pads 120c and the dummy pads 120e) on the back surface BS of the wafer substrate 101, the back surface BS of the wafer substrate 101 may be covered by the protective film 200. The protective film 200 may contact the plurality of pads (e.g., the chip pads 120c and the dummy pads 120e) disposed on the back surface BS of the wafer substrate 101, portions of the back surface BS of the wafer substrate 101 exposed between the chip pads 120c in the chip area CA, and portions of the dummy conductive layer 125 exposed between the dummy pads 120e in the edge area EA.

The protective film 200 may include a dicing tape. The protective film 200 may include a resin material formed of an organic material and the like.

The peeling force of the protective film 200 with respect to the dummy conductive layer 125 may be greater than the peeling force of the adhesive layer 300 with respect to the wafer substrate 101.

The method of manufacturing a semiconductor package according to example embodiments includes a process of forming (or maintaining) a dummy conductive layer 125 on the back surface BS of the wafer substrate 101 in the edge area EA, so that in the process of forming a protective film 200 covering the back surface BS of the wafer substrate 101 as a subsequent process, the protective film 200 comes into contact with the dummy conductive layer 125, thereby increasing the peeling force between the back surface BS of the wafer substrate 101 and the protective film 200. Accordingly, defects such as the protective film 200 protecting the back surface BS of the wafer substrate 101 being lifted or a void occurring between the back surface BS of the wafer substrate 101 and the protective film 200 may be significantly reduced or prevented.

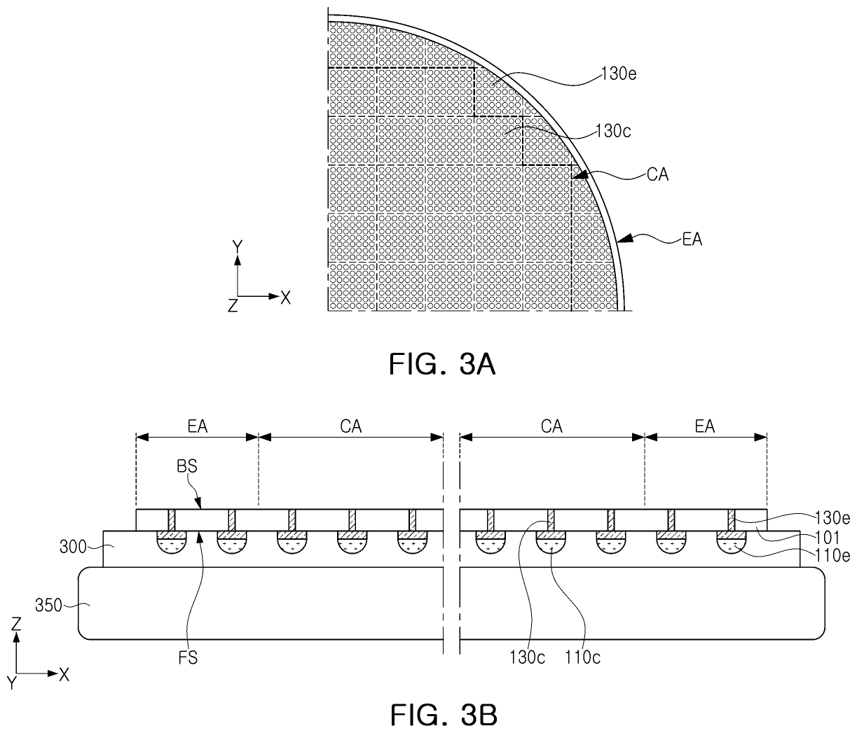

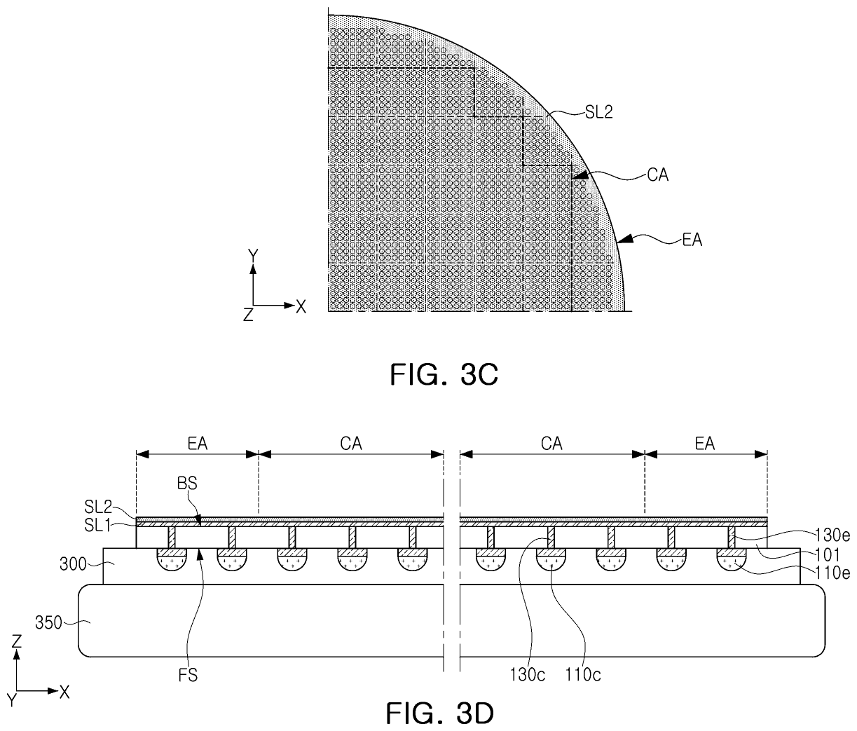

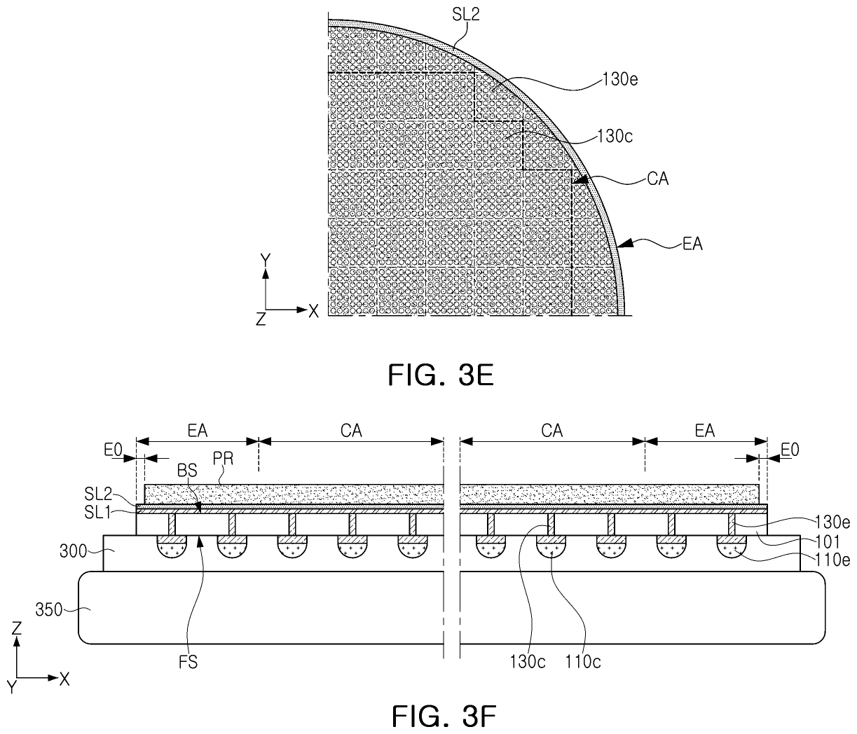

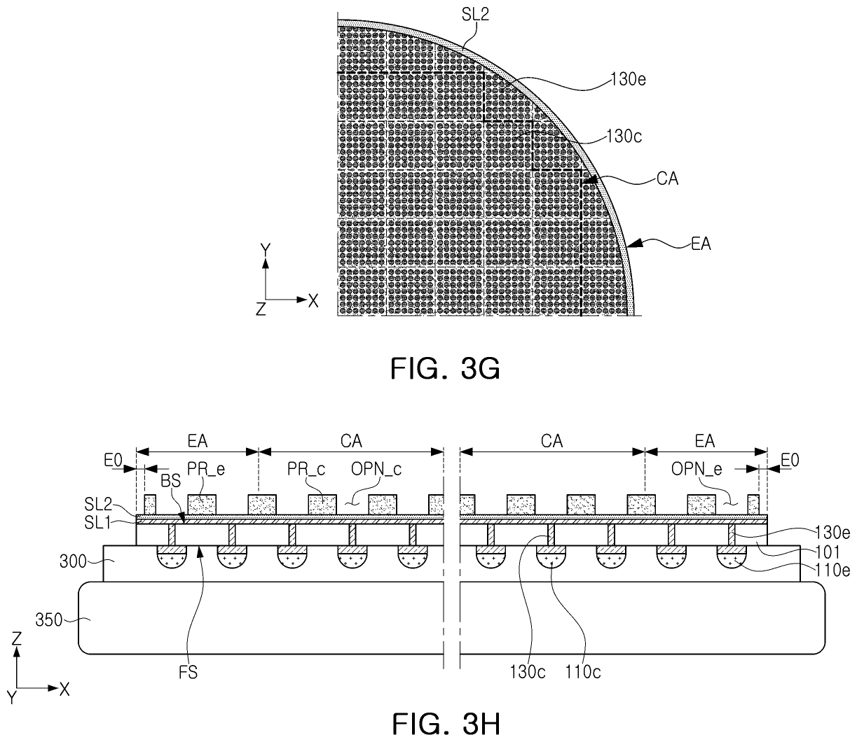

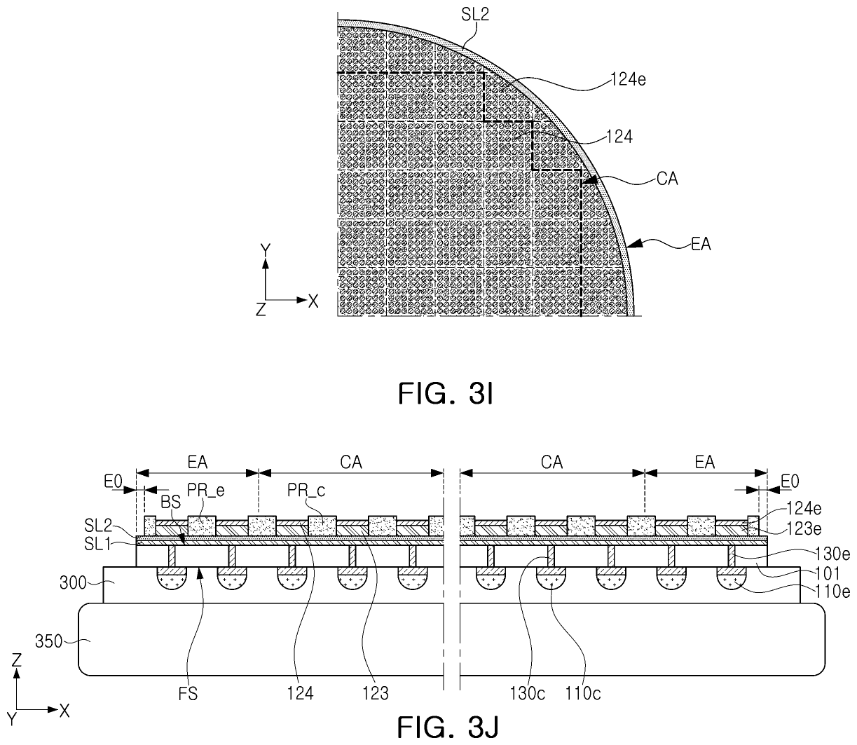

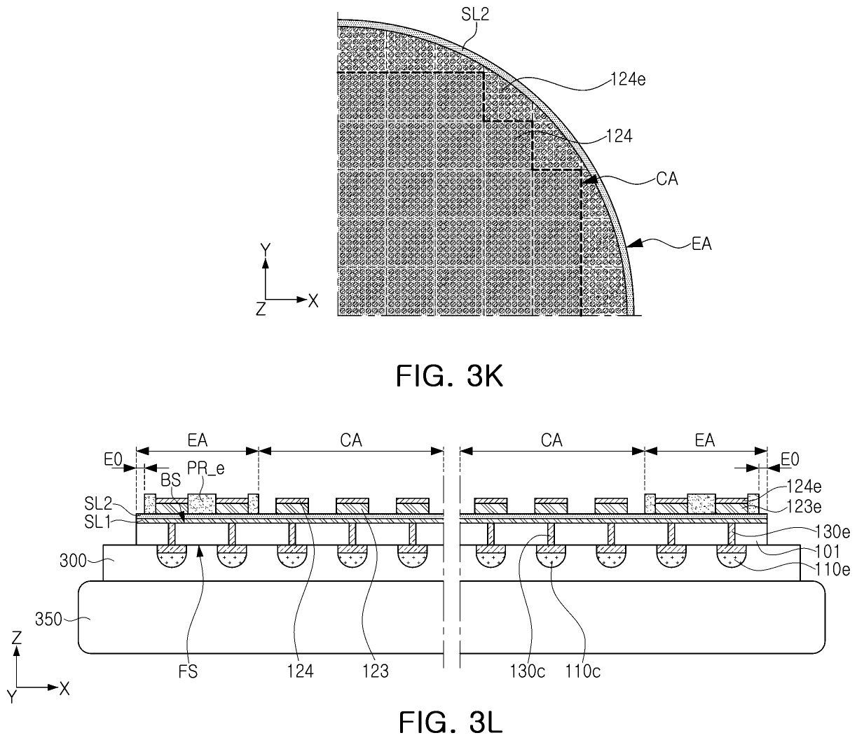

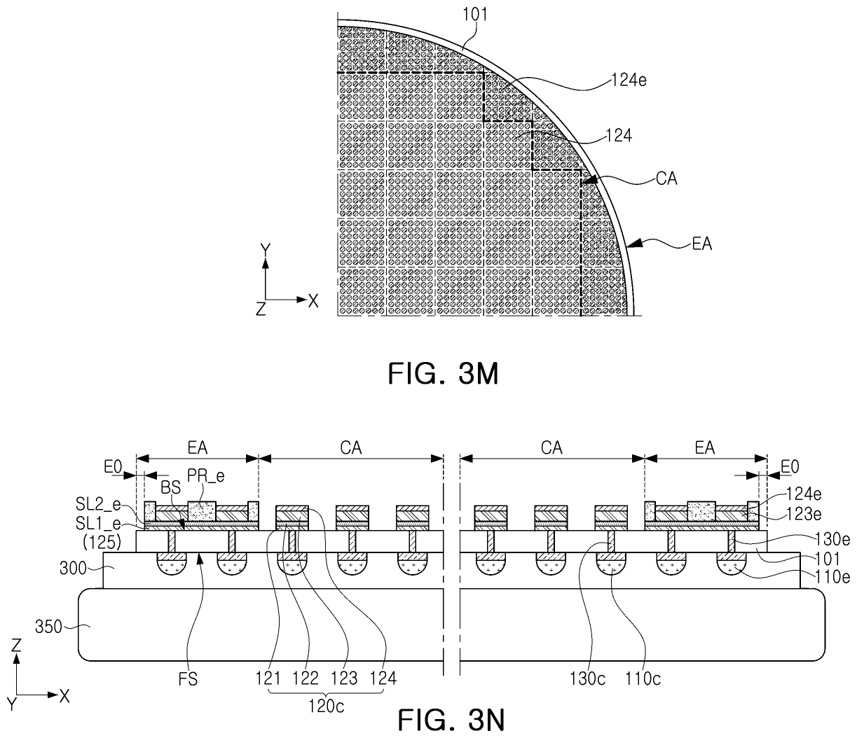

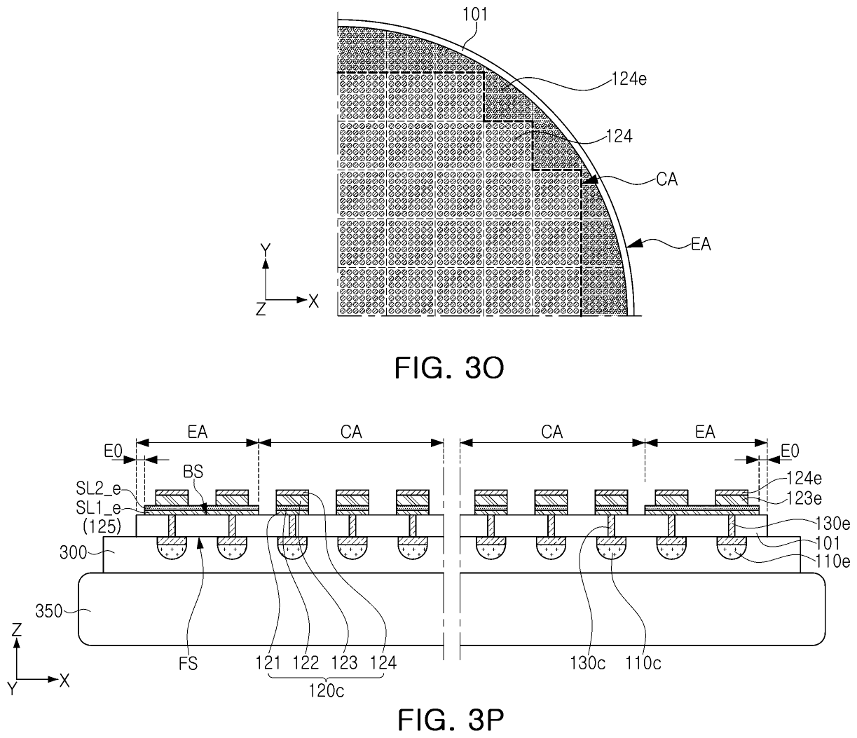

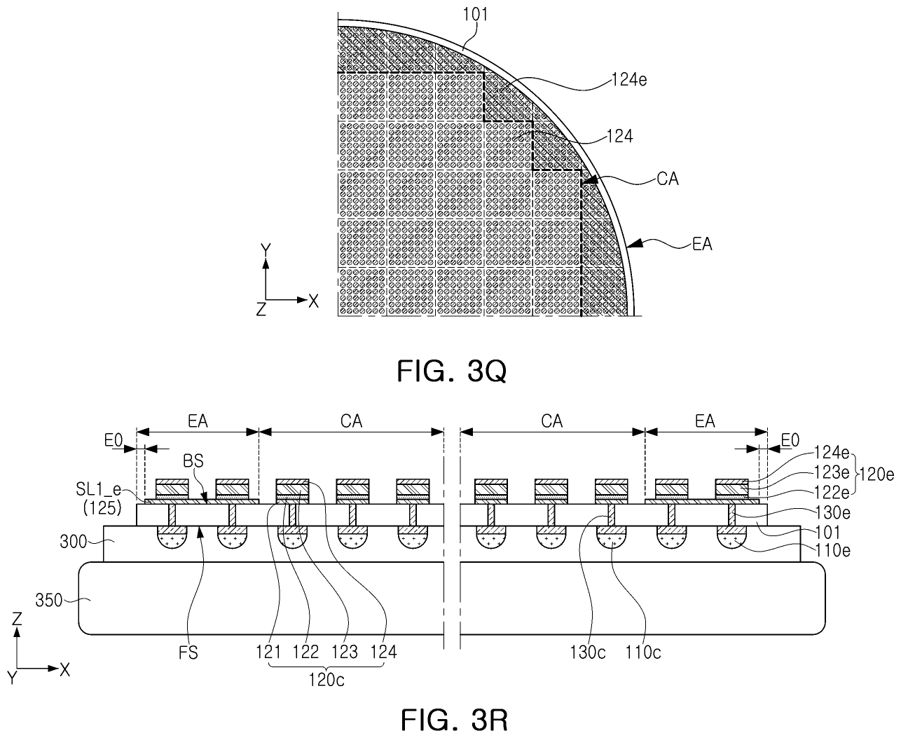

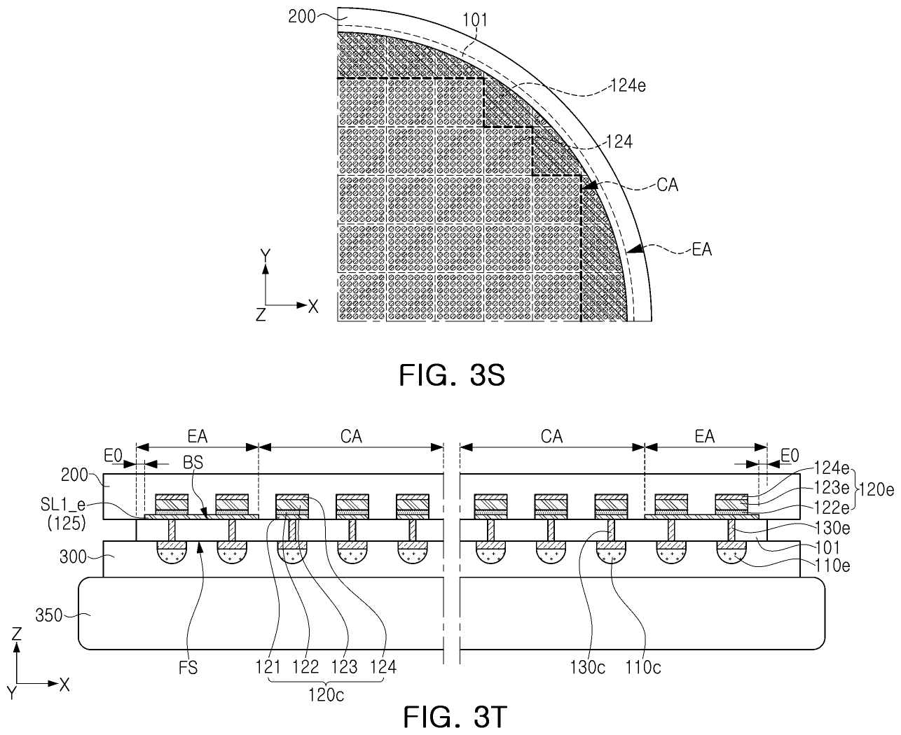

FIGS. 3A and 3T are drawings illustrating an example of a method of manufacturing a semiconductor package for illustrating a wafer substrate supporting process of the semiconductor package of FIGS. 2A and 2B. In particular, FIGS. 3A, 3C, 3E, 3G, 3I, 3K, 3M, 3O, 3Q, and 3S are plan views of a quarter region of a semiconductor package, and FIGS. 3B, 3D, 3F, 3H, 3J, 3L, 3N, 3P, 3R, and 3T are cross-sectional views corresponding to the quarter regions shown in FIGS. 3A, 3C, 3E, 3G, 3I, 3K, 3M, 3O, 3Q, and 3S, respectively.

Referring to FIGS. 3A and 3B, a method of manufacturing a semiconductor package may include an operation of forming a plurality of connection bumps 110c and dummy connection bumps 110e on a front surface FS of a wafer substrate 101, an operation of forming through-electrodes 130c and dummy through-electrodes 130e that penetrate the wafer substrate 101 from the front surface FS to the back surface BS and are connected to the plurality of connection bumps 110c and dummy connection bumps 110e, respectively, and an operation of forming a carrier substrate 350 that covers the front surface FS of the wafer substrate 101 with an adhesive layer 300 therebetween.

The plurality of connection bumps 110c and dummy connection bumps 110e may include a conductive material and may be formed by electro plating.

When the wafer substrate 101 is a silicon wafer, the through-electrodes 130c and the dummy through-electrodes 130e may be through silicon vias (TSVs). The through-electrodes 130c and the dummy through-electrodes 130e may be formed of a conductive material of at least one from among aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr).

A plurality of connection bumps (e.g., the connection bumps 110c and the dummy connection bumps 110e) and through-electrodes 130 (e.g., the through-electrodes 130c and the dummy through-electrodes 130e) may be formed in or on the chip area CA and the edge area EA such as, for example, across the entire surface FS of the wafer substrate 101.

After forming the carrier substrate 350 covering the front surface FS of the wafer substrate 101, the wafer substrate 101 may be turned over so that the front surface FS of the wafer substrate 101 faces downward. The back surface BS of the wafer substrate 101 may face upwards.

Referring to FIGS. 3C and 3D, an operation of sequentially forming a first conductive layer SL1 and a second conductive layer SL2 on the back surface BS of the wafer substrate 101 may be included.

The first conductive layer SL1 and the second conductive layer SL2 may be formed by a physical vapor deposition (PVD) process. However, embodiments of the disclosure are not limited thereto, and the first conductive layer SL1 and the second conductive layer SL2 may be formed by an atomic layer deposition (ALD) process, a chemical vapor deposition (CVD) process, a plasma enhancement CVD (PECVD) process, a low-pressure CVD (LPCVD) process, or the like.

The first conductive layer SL1 and the second conductive layer SL2 may completely cover the back surface BS of the wafer substrate 101.

The first conductive layer SL1 may be a first seed layer, and the second conductive layer SL2 may be a second seed layer. The first conductive layer SL1 may include titanium (Ti). However, embodiments of the disclosure are not limited thereto, and the first conductive layer SL1 may include, for example, titanium tungsten (TiW), and titanium nitride (TiN). The second conductive layer SL2 may include copper (Cu).

Referring to FIGS. 3E and 3F, an operation of forming a photoresist layer PR on the second conductive layer SL2 may be included. A photoresist solution may be applied on the second conductive layer SL2 and a soft bake may be performed to remove a portion of the solvent, thereby forming the photoresist layer PR. By applying a photoresist solution on the second conductive layer SL2 and melting a portion of the photoresist solution placed on the edge E0 of the edge area EA in the process of performing a soft bake, the second conductive layer SL2 may be exposed at the edge E0 of the edge area EA.

Referring to FIGS. 3G and 3H, a first mask may be placed on the photoresist layer PR, exposure light may be irradiated through a light-transmitting area of the first mask, and development may be performed to form photoresist patterns (a first photoresist pattern PR_c and a second photoresist pattern PR_e) including openings (e.g., a first opening OPN_c and a second opening OPN_e) that expose the second conductive layer SL2.

The photoresist patterns may include a first photoresist pattern PR_c formed on the chip area CA and including a first opening OPN_c, and a second photoresist pattern PR_e formed on the edge area EA and including a second opening OPN_e. The second conductive layer SL2 may be exposed through the first opening OPN_c and the second opening OPN_e.

The size of the first opening OPN_c of the first photoresist pattern PR_c may be substantially the same as the size of the second opening OPN_e of the second photoresist pattern PR_e. The first opening OPN_c and the second opening OPN_e may overlap with the through-electrode 130c and the dummy through electrode 130e in the vertical direction (Z-direction).

Referring to FIGS. 31 and 3J, conductive patterns may be formed within the first opening OPN_c and the second opening OPN_e. For example, a first conductive pattern 123 and a second conductive pattern 124 may be formed within first openings OPN_c on the chip area CA, and a first conductive pattern 123e and a second conductive pattern 124e may be formed within second openings OPN_e on the edge area EA.

The conductive patterns (e.g., the first conductive patterns 123 and 123e and the second conductive patterns 124 and 124e) may be formed through electro plating. The operation of forming the conductive patterns (e.g., the first conductive patterns 123 and 123e and the second conductive patterns 124 and 124e) may include an operation of applying a voltage through the second conductive layer SL2 exposed at an edge E0 of the edge area EA. Accordingly, a uniform voltage may be maintained across the entirety of the second conductive layer SL2 during the process of forming the conductive patterns (e.g., the first conductive patterns 123 and 123e and the second conductive patterns 124 and 124e).

The conductive patterns may include first conductive patterns 123 and 123e and second conductive patterns 124 and 124e on the first conductive patterns 123 and 123e, which are formed on portions of the second conductive layer SL2 exposed through the first openings OPN_c and the second openings OPN_e. The first conductive pattern 123 and the second conductive pattern 124 on the first conductive pattern 123 may be formed within each of the first openings OPN_c. Within each of the second openings OPN_e, a first conductive pattern 123e and a second conductive pattern 124e on the first conductive pattern 123e may be formed.

The first conductive patterns 123 and 123e may include a first metal material, and the second conductive patterns 124 and 124e may include a second metal material different from the first metal material. For example, the first metal material may include nickel (Ni), and the second metal material may include gold (Au). The first conductive patterns 123 and 123e may be metal films, and the second conductive patterns 124 and 124e may be barrier films for the first conductive patterns 123 and 123e.

The thickness of the first conductive patterns 123 and 123e in the vertical direction (Z-direction) may be greater than the thickness of the second conductive patterns 124 and 124e in the vertical direction (Z-direction).

The first conductive pattern 123 and the second conductive pattern 124 on the chip area CA may correspond to the third metal layer (e.g., first conductive pattern 123) and the fourth metal layer (e.g., second conductive pattern 124) of the chip pad 120c of FIGS. 2A and 2B. The first conductive pattern 123e and the second conductive pattern 124e on the edge area EA may be the second dummy electrode layer and the third dummy electrode layer of FIGS. 2A and 2B.

Referring to FIGS. 3K and 3L, the first photoresist patterns PR_c on the chip area CA may be removed. By removing the first photoresist patterns PR_c on the chip area CA, portions of the second conductive layer SL2 between the first conductive pattern 123 and the second conductive pattern 124 on the chip area CA may be exposed.

A second mask may be placed on the first photoresist pattern PR_c, exposure light may be irradiated through the light-transmitting area of the second mask, and development may be performed to remove the first photoresist patterns PR_c.

Referring to FIGS. 3M and 3N, portions of the first conductive layer SL1 and the second conductive layer SL2 on the chip area CA that were overlapping with the first photoresist patterns PR_c of FIG. 3J may be removed. For example, portions of the first conductive layer SL1 and the second conductive layer SL2 that do not overlap with the first conductive pattern 123 and the second conductive pattern 124 on the chip area CA may be removed. The portions of the first conductive layer SL1 and the second conductive layer SL2 that do not overlap with the first conductive pattern 123 and the second conductive pattern 124 on the chip area CA may be removed by a wet etching process.

A portion of the first conductive layer SL1 exposed between the first conductive pattern 123 and the second conductive pattern 124 on the chip area CA may be removed, and a portion of the second conductive layer SL2 exposed as the portion of the first conductive layer SL1 is removed may be sequentially removed. By removing portions of the first conductive layer SL1 and the second conductive layer SL2 between the first conductive pattern 123 and the second conductive pattern 124 on the chip area CA, chip pads 120c in contact with the back surface BS of the wafer substrate 101 may be formed, and portions of the wafer substrate 101 between the chip pads 120c may be exposed.

Portions of the first conductive layer SL1 and the second conductive layer SL2 overlapping with the first conductive pattern 123 and the second conductive pattern 124 may form the first metal layer 121 and the second metal layer 122 of the chip pad 120c.

Referring to FIGS. 3O and 3P, the second photoresist patterns PR_e on the edge area EA may be removed. The second photoresist patterns PR_e may be removed through a strip/ashing process. As the second photoresist patterns PR_e are removed, a portion of the second conductive layer SL2_e on the edge area EA may be exposed. A portion of the second conductive layer SL2_e that does not overlap with the first conductive pattern 123e and the second conductive pattern 124e may be exposed.

FIGS. 3Q and 3R illustrate that the portion of the second conductive layer SL2_e exposed on the edge area EA may be removed. The portion of the second conductive layer SL2_e exposed on the edge area EA may be removed by a wet etching process. The second conductive layer SL2_e on the edge area EA may include a first portion that overlaps with the first conductive pattern 123e and the second conductive pattern 124e, and an exposed second portion between the first conductive patterns 123e and the second conductive patterns 124e. The second portion of the second conductive layer SL2_e on the edge area EA that does not overlap with the first conductive patterns 123e and the second conductive patterns 124e may be removed. By removing the exposed portion (e.g., the second portion) of the second conductive layer SL2_e, dummy pads 120e may be formed, and a portion of the first conductive layer SL1_e on the edge area EA may be exposed. A portion of the second conductive layer SL2_e that overlaps with the first conductive pattern 123e and the second conductive pattern 124e on the edge area EA may form the first dummy electrode layer 122e of the dummy pads 120e. The exposed portion of the first conductive layer SL1_e on the edge area EA may correspond to the dummy conductive layer 125 of FIGS. 2A and 2B.

Referring to FIGS. 3S and 3T, a protective film 200 covering the back surface BS of the wafer substrate 101 may be formed. The back surface BS of the wafer substrate 101 and the protective film 200 may be bonded. The protective film 200 may be in contact with the exposed portion of the first conductive layer SL1_e on the edge area EA.

Next, referring to FIGS. 2A and 2B together, after the process of forming the protective film 200, the carrier substrate 350 positioned on the front surface FS of the wafer substrate 101 may be removed together with the adhesive layer 300. In the process of removing the carrier substrate 350 and the adhesive layer 300, the protective film 200 formed on the back surface BS of the wafer substrate 101 may be in a state of being bonded to the back surface BS of the wafer substrate 101.

The peeling force of the protective film 200 on the exposed portion of the first conductive layer SL1_e may be greater than the peeling force of the adhesive layer 300 on the wafer substrate 101. For example, the peeling force of the protective film 200 for the exposed portion of the first conductive layer SL1_e may be about 6 N/in. The peeling force of the adhesive layer 300 for the wafer substrate 101 may be about 1 N/in.

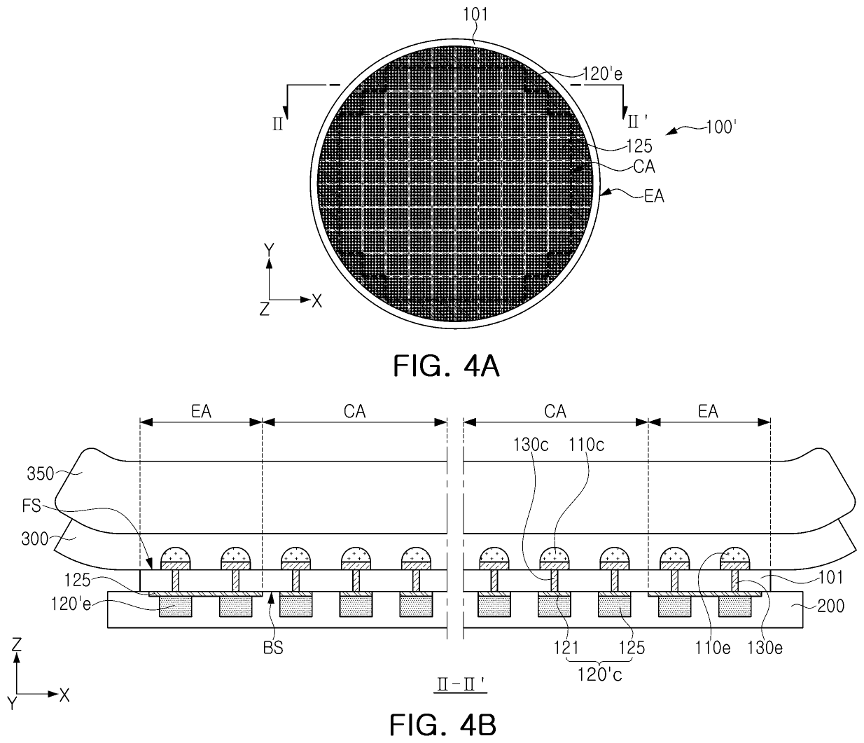

FIGS. 4A and 4B are drawings illustrating a wafer substrate supporting process of a semiconductor package in a method of manufacturing a semiconductor package according to another embodiment. FIGS. 4A and 4B are a second plan view illustrating another embodiment of a wafer substrate supporting process operation of a semiconductor package and a second cross-sectional view along a line II-II′ of the second plan view, respectively.

Referring to FIGS. 4A and 4B, a wafer substrate supporting process 100′ may refer to a process of forming a carrier substrate 350 covering the front surface FS of the wafer substrate 101 to protect the front surface FS of the wafer substrate 101 prior to the process of forming a plurality of pads (e.g., chip pads 120′c and dummy pads 120′e) on the back surface BS of the wafer substrate 101, and a process of forming a protective film 200 covering the back surface BS of the wafer substrate 101 to protect the back surface BS of the wafer substrate 101 after the process of forming a plurality of pads (e.g., the chip pads 120′c and the dummy pads 120′e) on the back surface of the wafer substrate 101 and prior to the dicing process for the wafer substrate 101.

The remaining configurations, except for the plurality of pads (e.g., the chip pads 120′c and the dummy pads 120′e), may be identical to or corresponding to the configurations illustrated in FIGS. 2A and 2B. Except for the plurality of pads (e.g., the chip pads 120′c and the dummy pads 120′e), repetitive description of the components that are identical or corresponding to the components illustrated in FIG. 2 may be omitted.

The wafer substrate 101 may include a front surface FS on which a plurality of connection bumps 110c and dummy connection bumps 110e are formed and a back surface BS facing in a direction opposite a facing direction of the front surface FS on which the plurality of pads (e.g., the chip pads 120′c and the dummy pads 120′e) are formed.

Each of the chip pads 120′c may include a first metal layer 121 and a fifth metal layer 135 in contact with the lower surface of the first metal layer 121, sequentially stacked on the lower surface of the wafer substrate 101.

The dummy pads 120′e may be respectively disposed on the lower surface of a dummy conductive layer 125 disposed on the lower surface of the wafer substrate 101. The dummy pads 120′e disposed on the lower surface of the wafer substrate 101 on the edge area EA may be on a same one from among dummy conductive layers 125.

The dummy pad 120′e and the fifth metal layer 135 may include the same material as each other. For example, the dummy pad 120′e and the fifth metal layer 135 may include copper (Cu). The dummy pad 120′e and the fifth metal layer 135 may be disposed at the same level as each other. In an example, the lower surface of the dummy pad 120′e may be disposed at the same level as the lower surface of the fifth metal layer 135.

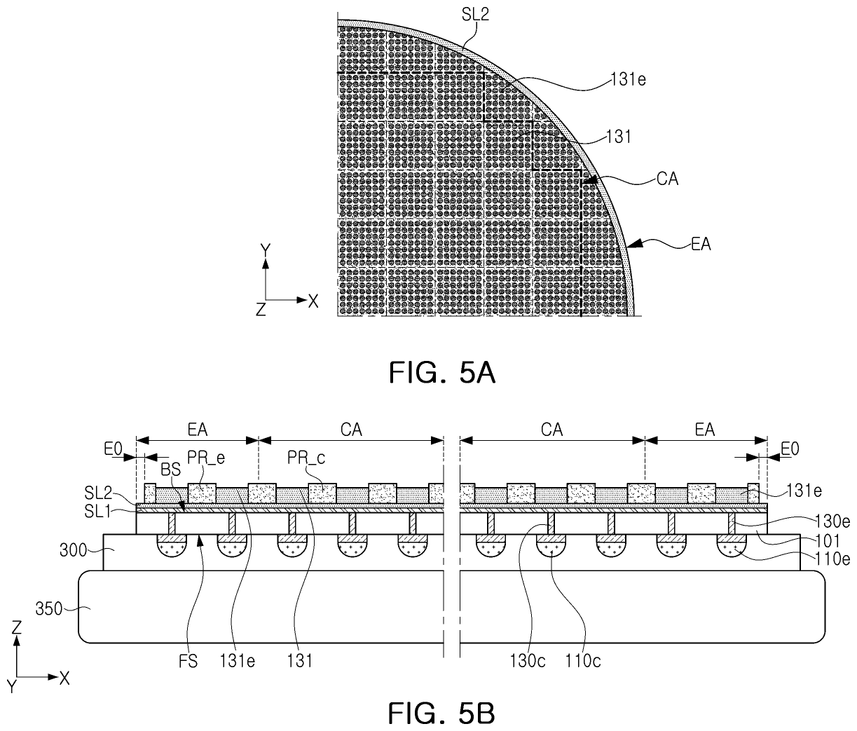

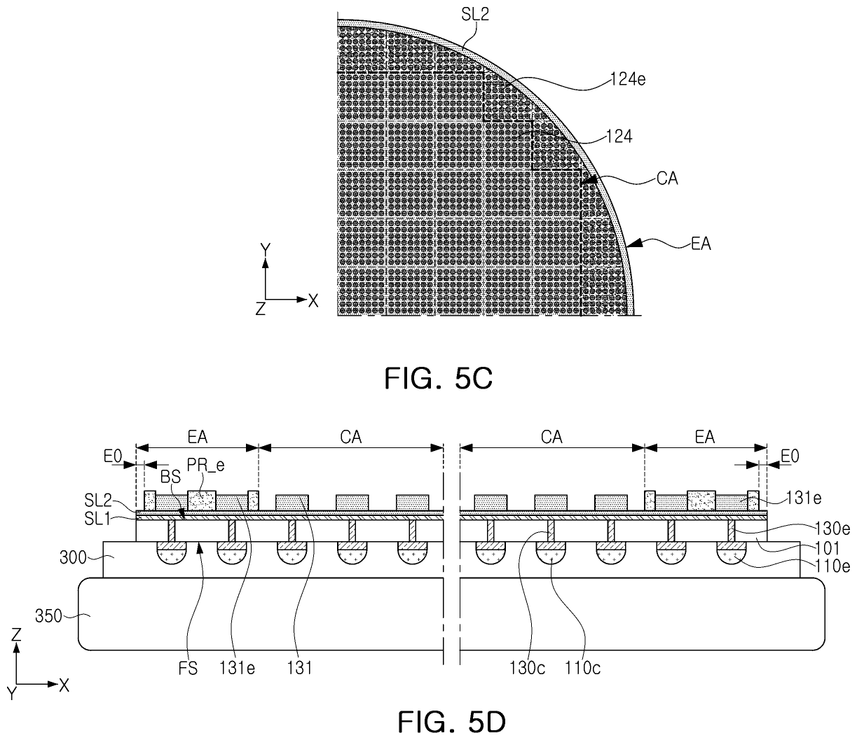

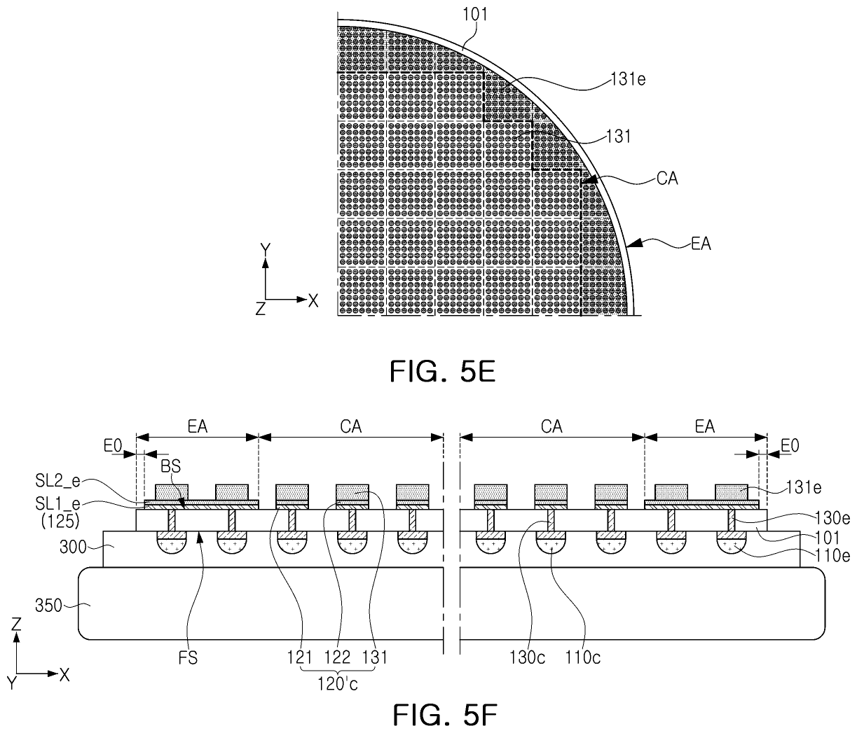

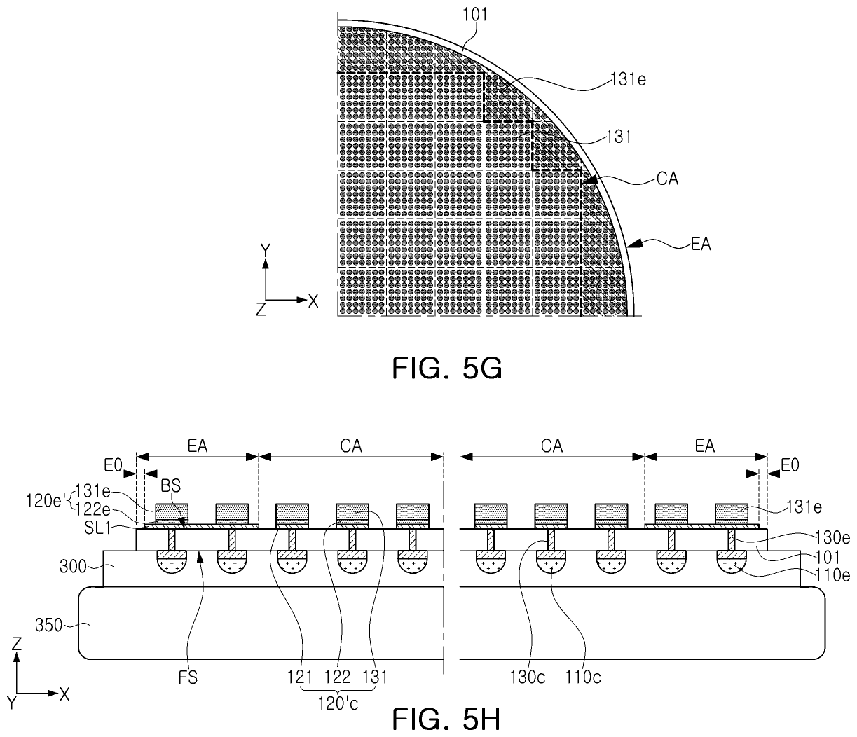

FIGS. 5A to 5H are drawings illustrating an example embodiment of a method of manufacturing a semiconductor package for illustrating a wafer substrate supporting process of the semiconductor package of FIGS. 4A and 4B. In particular, FIGS. 5A, 5C, 5E, and 5G are plan views of a quarter region of a semiconductor package, and FIGS. 5B, 5D, 5F, and 5H are cross-sectional views corresponding to the quarter regions shown in FIGS. 5A, 5C, 5E, and 5G, respectively.

In the wafer substrate supporting process 100′ of the semiconductor package of FIGS. 4A and 4B, the process operations illustrated in FIGS. 3A—to 3Tmay be applied in the same manner, and FIGS. 5A to 5H illustrate subsequent processes after the process described above with reference to FIGS. 3G and 3H.

Referring to FIGS. 5A and 5B, third conductive patterns 131 and 131e may be formed within the openings (e.g., first opening OPN_c and second openings OPN_e) of FIG. 3H. The third conductive patterns 131 may be formed within the first openings OPN_c on the chip area CA, and the third conductive patterns 131e may be formed within the second openings OPN_e on the edge area EA.

The third conductive patterns 131 and 131e may be formed through electro plating. The operation of forming the third conductive patterns 131 and 131e may include a process of applying a voltage through a portion of the second conductive layer SL2 exposed at the edge E0 of the edge area EA. Accordingly, a uniform voltage may be maintained across the entirety of the second conductive layer SL2 during the process of forming the third conductive patterns 131 and 131e.

The third conductive patterns 131 and 131e may be formed on portions of the second conductive layer SL2 exposed through the first openings OPN_c and the second openings OPN_e.

The third conductive patterns 131 and 131e may include a third metal material different from the first and second metal materials. In an example, the third conductive patterns 131 and 131e may include the same material as the second conductive layer SL2. For example, the third conductive patterns 131 and 131e and the second conductive layer SL2 may include copper (Cu).

Referring to FIGS. 5D and 5F, the first photoresist patterns PR_c on the chip area CA and portions of the first conductive layer SL1 and the second conductive layer SL2 on the chip area CA overlapping with the first photoresist patterns PR_c may be removed. After the process of removing the portions of the first conductive layer SL1 and the second conductive layer SL2, the second photoresist pattern PR_e on the edge area EA may be removed.

By removing the portions of the first conductive layer SL1 and the second conductive layer SL2 between the third conductive patterns 131 on the chip area CA, chip pads 120′c that come into contact with the back surface BS of the wafer substrate 101 may be formed, and portions of the wafer substrate 101 between the chip pads 120′c may be exposed. In an example, each of the chip pads 120′c may include a first metal layer 121, a second metal layer 122 on the first metal layer 121, and a third conductive pattern 131 on the second metal layer 122. The second metal layer 122 may be a portion of the second conductive layer SL2 that overlaps with the third conductive pattern 131. The second metal layer 122 and the third conductive pattern 131 may form the fifth metal layer 135 of FIGS. 4A and 4B. Since the third conductive pattern 131 and the second metal layer 122 may include the same metal material, there may be no interface distinction.

As the second photoresist patterns PR_e are removed, a portion of the second conductive layer SL2_e on the edge area EA may be exposed. The portion of the second conductive layer SL2_e that does not overlap with the third conductive patterns 131e may be exposed.

Referring to FIGS. 5G and 5H, the portion of second conductive layer SL2_e exposed on the edge area EA may be removed. By removing the exposed portion of the second conductive layer SL2_e, dummy pads 120′e may be formed, and a portion of the first conductive layer SL1_e on the edge area EA may be exposed. Each of the dummy pads 120′e may include a first dummy electrode layer 122e and a third conductive pattern 131e. The first dummy electrode layer 122e may be a portion of the second conductive layer SL2_e that overlaps with the third conductive pattern 131e. The conductive patterns 131e may include the same metal material as a material of the first dummy electrode layer 122e, and thus, interfaces thereof may not be distinguished.

Next, referring to FIGS. 4A and 4B, a protective film 200 covering the back surface BS of the wafer substrate 101 may be formed, and after the process of forming the protective film 200, the carrier substrate 350 formed on the front surface FS of the wafer substrate 101 may be removed together with the adhesive layer 300.

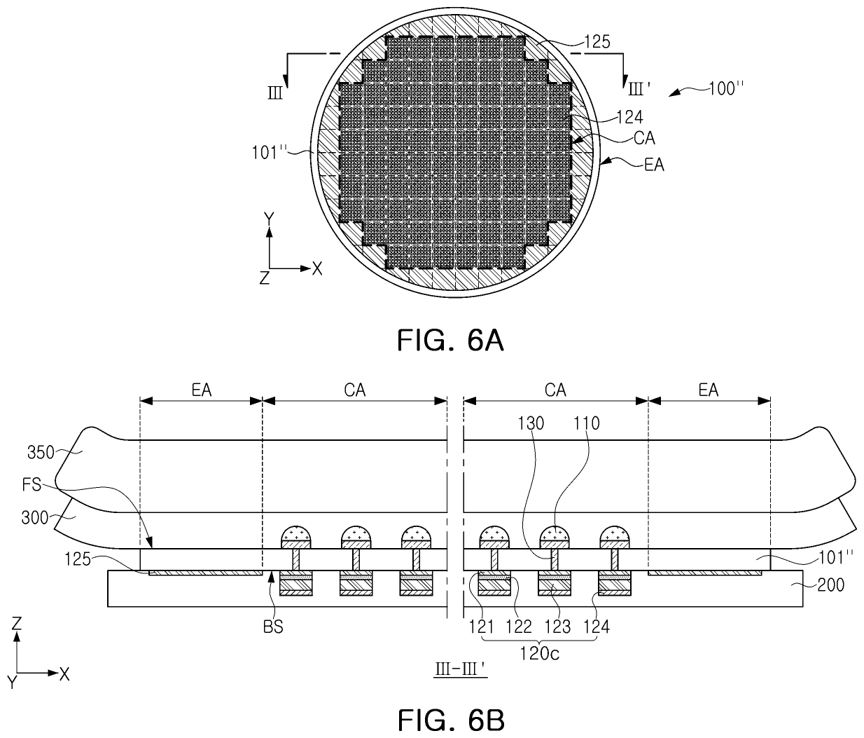

FIGS. 6A and 6B are drawings illustrating a wafer substrate supporting process of a semiconductor package in a method of manufacturing a semiconductor package according to another embodiment. FIGS. 6A and 6B show a third plan view and a second cross-sectional view along a line III-III′ of the third plan view, respectively, which illustrate another embodiment of a wafer substrate supporting process operation of a semiconductor package.

Referring to FIGS. 6A and 6B, the wafer substrate supporting process 100″ may be a process of forming a carrier substrate 350 covering the front surface FS of the wafer substrate 101″ to protect the front surface FS of the wafer substrate 101″ prior to a process of forming a plurality of pads (e.g., the chip pads 120c and the dummy pads 120e) on the back surface BS of the wafer substrate 101″, and a process of forming a protective film 200 covering the back surface BS of the wafer substrate 101 prior to a dicing process for the wafer substrate 101″ after the process of forming a plurality of pads (e.g., the chip pads 120c and the dummy pads 120e) on the back surface of the wafer substrate 101″ to protect the back surface BS of the wafer substrate 101. The carrier substrate 350 and the protective film 200 may protect the wafer substrate 101″ from contamination or physical/chemical damage due to contact with the external environment, and the protective film 200 may prevent cracks or the like from occurring during the dicing process.

The remaining configurations except for the wafer substrate 101″ may be identical to or corresponding to the configurations illustrated in FIGS. 2A and 2B. Duplicate descriptions of components among the configurations except for the wafer substrate 101″ that are identical to or corresponding to the configurations illustrated in FIGS. 2A and 2B may be omitted.

Referring to FIGS. 6A and 6B, the dummy conductive layer 125 may be completely exposed on the back surface BS of the wafer substrate 101″.

A plurality of pad areas may not be formed on the edge area EA of the wafer substrate 101″. For example, a plurality of connection bumps 110, a plurality of chip pads 120c, and through-electrodes 130 may be formed only on the chip area CA of the wafer substrate 101″.

Since the dummy conductive layer 125 is completely exposed on the back surface BS of the wafer substrate 101″, a bonding area between the protective film 200 and the dummy conductive layer 125 covering a relatively wide back surface of the wafer substrate 101″ may be secured. Accordingly, the peeling phenomenon of the protective film 200 on the back surface BS of the wafer substrate 101″ may be significantly reduced or prevented.

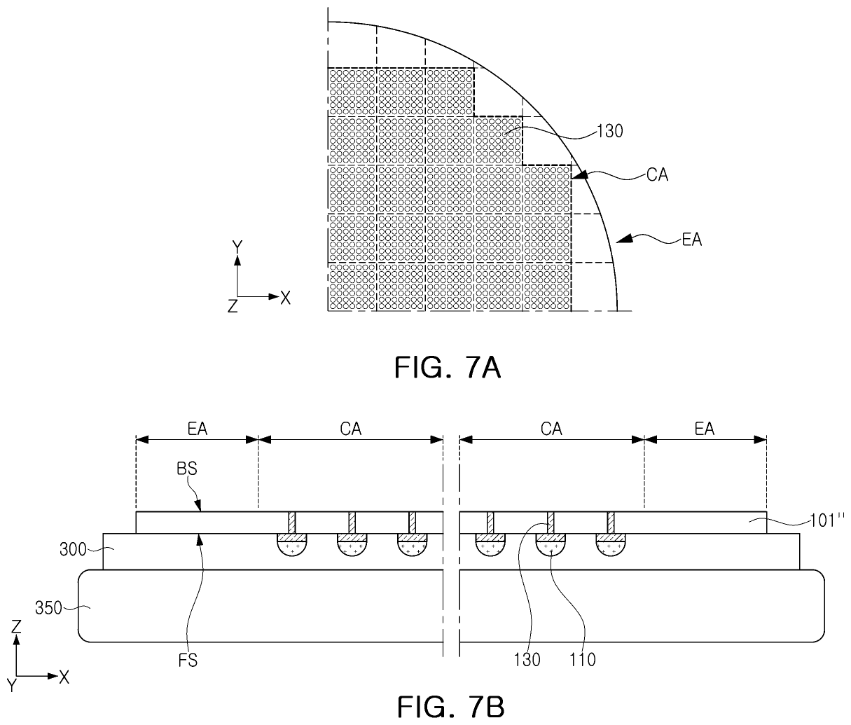

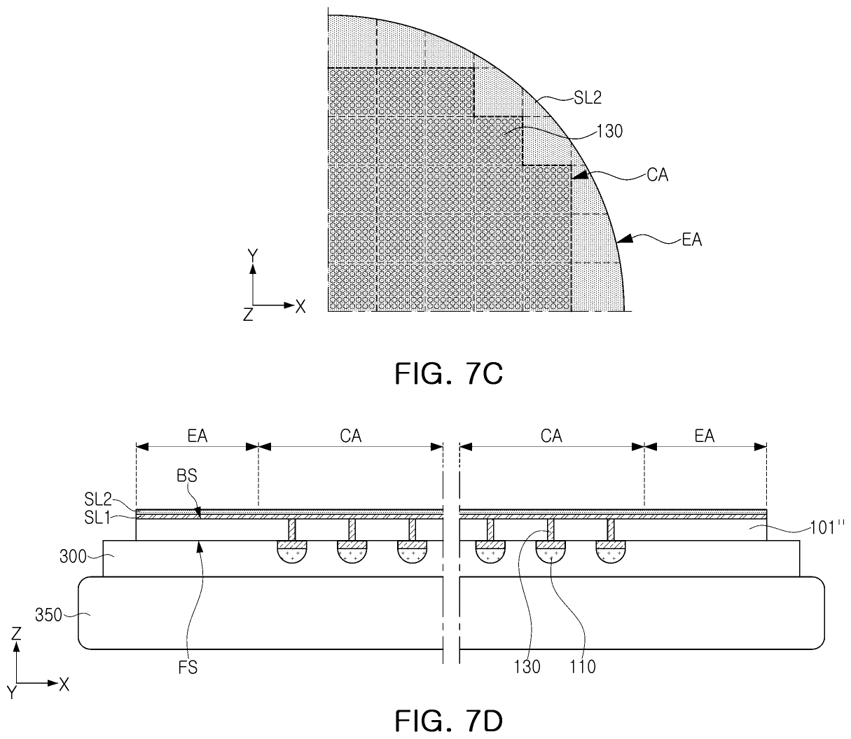

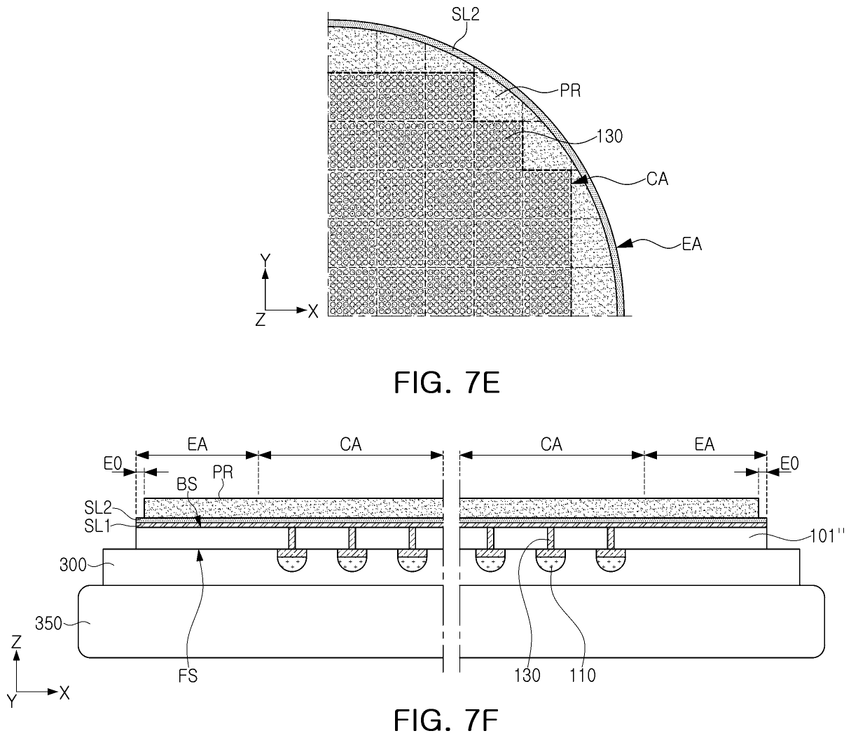

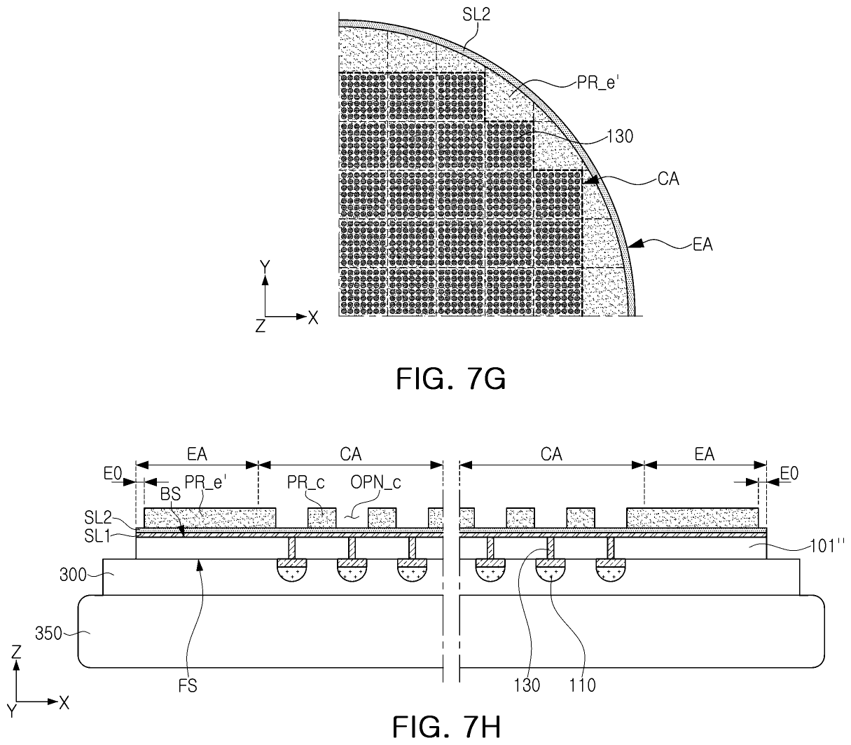

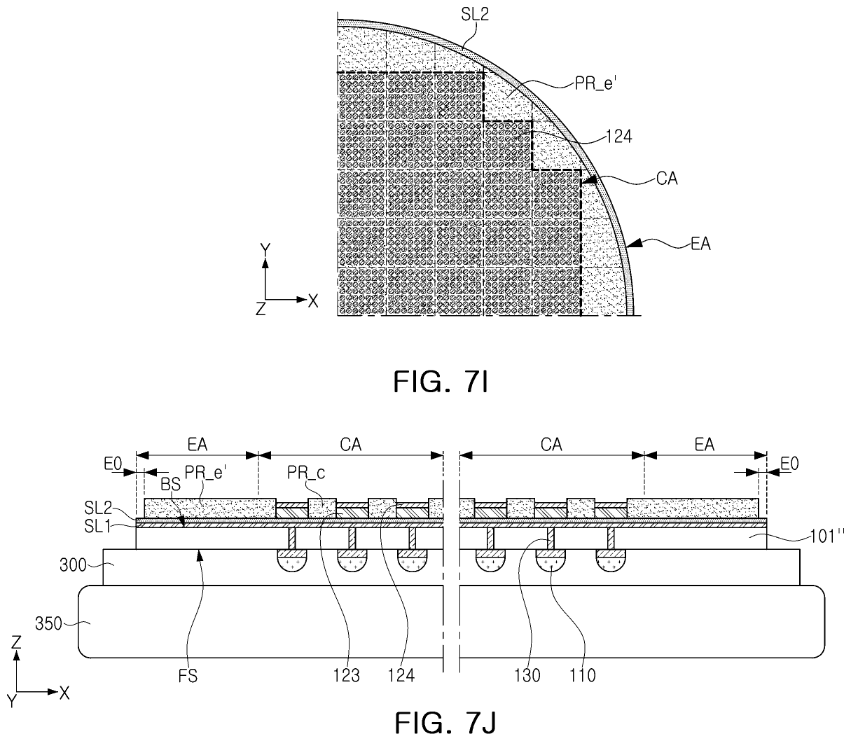

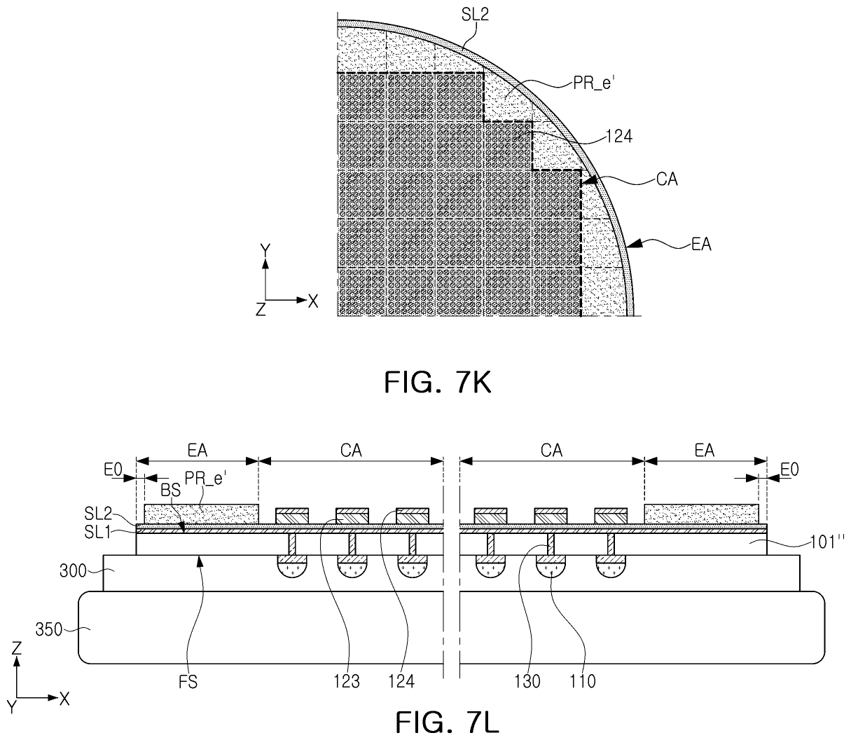

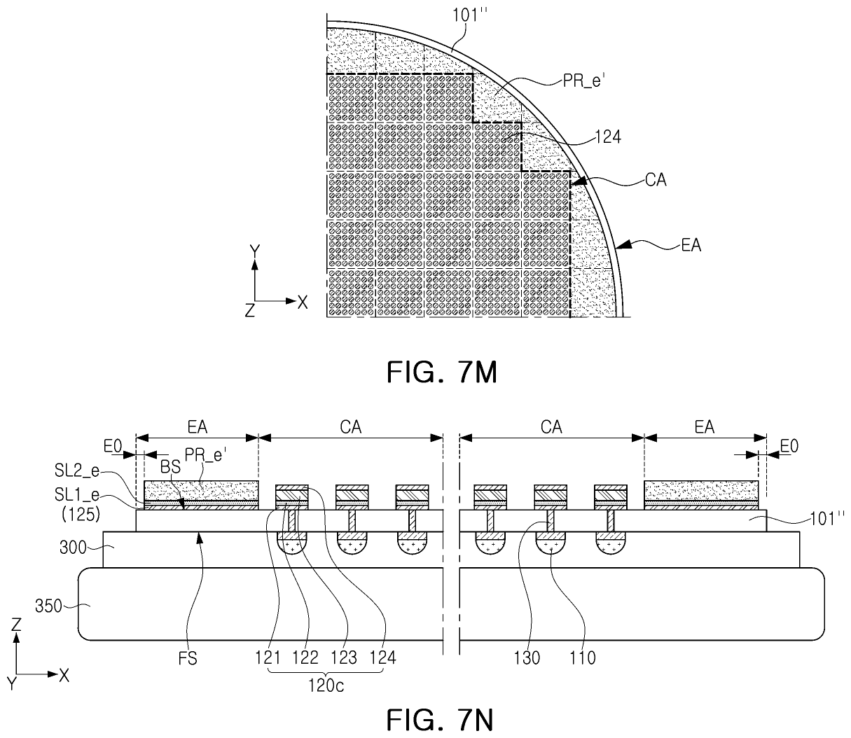

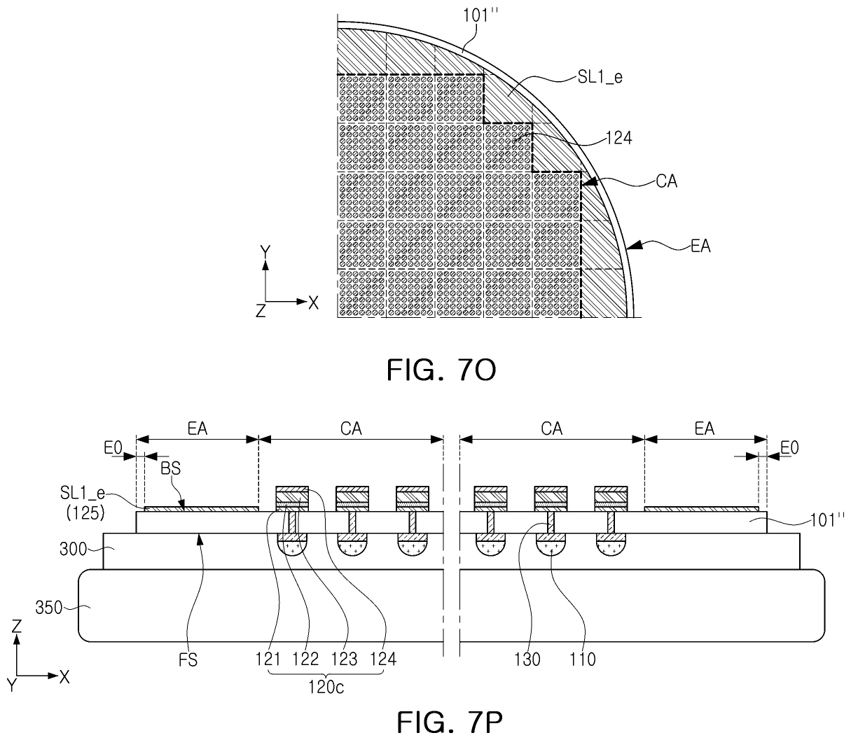

FIGS. 7A- to 7P are drawings illustrating an example embodiment of a method of manufacturing a semiconductor package for illustrating a wafer substrate supporting process of a semiconductor package of FIGS. 6A and 6B. In particular, FIGS. 7A, 7C, 7E, 7G, 7I, 7K, 3M, and 3O are plan views of a quarter region of a semiconductor package, and FIGS. 7B, 7D, 7F, 7H, 7J, 7L, 7N, and 7P are cross-sectional views corresponding to the quarter regions shown in FIGS. 7A, 7C, 7E, 7G, 7I, 7K, 3M, and 3O, respectively.

Referring to FIGS. 7A and 7B, the method of manufacturing a semiconductor package may include an operation of forming a plurality of connection bumps 110 on the front surface FS of a wafer substrate 101″, an operation of forming through-electrodes 130 that penetrate the wafer substrate 101″ from the front surface FS to the back surface BS of the wafer substrate 101″ and are connected to the plurality of connection bumps 110, and an operation of forming a carrier substrate 350 that covers the front surface FS of the wafer substrate 101 with an adhesive layer 300 therebetween.

Referring to FIGS. 7C to 7F, the method of manufacturing the semiconductor package may include an operation of sequentially forming a first conductive layer SL1 and a second conductive layer SL2 on the back surface BS of the wafer substrate 101″ and an operation of forming a photoresist layer PR on the second conductive layer SL2.

Referring to FIGS. 7G and 7H, the method of manufacturing the semiconductor package may include an operation of forming a first photoresist pattern PR_c including first openings OPN_c exposing the second conductive layer SL2 on the chip area CA by disposing a third mask on the photoresist layer PR disposed on the chip area CA, irradiating exposure light through a light-transmitting area of the third mask, and developing the same. A portion of the photoresist layer PR formed on the edge area EA may be referred to as the second photoresist pattern PR_e′.

Referring to FIGS. 7I to 7N, the method of manufacturing the semiconductor package may include an operation of forming first conductive patterns 123 and second conductive patterns 124 within the first openings OPN_c on the chip area CA, an operation of removing the first photoresist pattern PR_c on the chip area CA, and an operation of removing portions of the first conductive layer SL1 and the second conductive layer SL2 overlapping with the first photoresist pattern PR_c.

Referring to FIGS. 7O and 7P, the method of manufacturing the semiconductor package may include an operation of removing the second photoresist pattern PR_e′ formed on the edge area EA and an operation of removing portions of the second conductive layer SL2_e overlapping with the second photoresist pattern PR_e′. By removing the second conductive layer SL2_e of the edge area EA, the first conductive layer SL1_e may be completely exposed on the back surface BS of the wafer substrate 101.

Next, referring to FIGS. 6A and 6B, a protective film 200 covering the back surface BS of the wafer substrate 101″ may be formed. After the process of forming the protective film 200, the carrier substrate 350 formed on the front surface FS of the wafer substrate 101 may be removed together with the adhesive layer 300.

As set forth above, a method of manufacturing a semiconductor package according to example embodiments may increase adhesive strength between a back surface of a wafer substrate and a protective film by allowing a portion of a conductive layer constituting each of pads to remain in an edge area of the wafer substrate during a process of forming pads on the back surface of the wafer substrate. Accordingly, the method of manufacturing a semiconductor package may be provided by improving a peeling phenomenon of the protective film disposed on the back surface of the wafer substrate, thereby improving a process yield and providing a semiconductor package having improved reliability.

While non-limiting example embodiments have been described above with reference to the accompanying drawings, it will be apparent to those skilled in the art that modifications and variations could be made without departing from spirit and scope of the present disclosure.

What is claimed is:

1. A method of manufacturing a semiconductor package, the method comprising:
providing a wafer substrate including a first surface, a second surface opposite to the first surface, a chip area, and an edge area surrounding the chip area;
sequentially forming a first conductive layer and a second conductive layer on the second surface;
forming a photoresist pattern, including openings exposing the second conductive layer, on the second conductive layer, wherein the photoresist pattern includes a first photoresist pattern on the chip area and a second photoresist pattern on the edge area;
forming conductive patterns within the openings;
removing the first photoresist pattern on the chip area from the photoresist pattern, and portions of the first conductive layer and the second conductive layer overlapping the first photoresist pattern;
removing the second photoresist pattern on the edge area from the photoresist pattern, and a first portion of the second conductive layer overlapping the second photoresist pattern, such that at least a first portion of the first conductive layer on the edge area is exposed; and
forming a protective film on the second surface such that the protective film is on the conductive patterns.

2. The method of claim 1, wherein the first conductive layer includes the first portion on the edge area and overlapping the second photoresist pattern, and a second portion on the edge area and overlapping the conductive patterns, and
wherein the first portion of the first conductive layer is exposed by the removing the second photoresist pattern on the edge area and the first portion of the second conductive layer overlapping the second photoresist pattern.

3. The method of claim 1, wherein the first conductive layer includes titanium (Ti), and
wherein the second conductive layer includes copper (Cu).

4. The method of claim 1, wherein the forming the conductive patterns comprises forming a first conductive pattern on a second portion of the second conductive layer exposed through the openings, and forming a second conductive pattern on the first conductive pattern, and
wherein a thickness of the first conductive pattern is greater than a thickness of the second conductive pattern.

5. The method of claim 4, wherein the first conductive pattern includes nickel (Ni), and
wherein the second conductive pattern includes gold (Au).

6. The method of claim 1, wherein the forming the conductive patterns comprises forming a first conductive pattern on a second portion of the second conductive layer exposed through the openings,
wherein the first conductive pattern includes a material that is the same as a material of the second conductive layer.

7. The method of claim 6, wherein the second conductive layer and the first conductive pattern include copper (Cu).

8. The method of claim 1, wherein the forming the photoresist pattern comprises:
applying a photoresist layer on the second conductive layer; and
forming the openings that expose the second conductive layer by irradiating the photoresist layer with exposure light and performing developing.

9. The method of claim 8, wherein the openings are in the first photoresist pattern and the second photoresist pattern.

10. The method of claim 8, wherein the openings are in the first photoresist pattern and are not in the second photoresist pattern.

11. The method of claim 8, wherein the forming the photoresist pattern further comprises exposing an edge of the second conductive layer on the edge area by melting a portion of the photoresist layer, and
wherein the applying the photoresist layer on the second conductive layer is performed prior to the forming the openings.

12. The method of claim 1, wherein the sequentially forming the first conductive layer and the second conductive layer comprises depositing each of the first conductive layer and the second conductive layer by a physical vapor deposition (PVD) process, and
wherein the forming the conductive patterns comprises forming the conductive patterns by an electro plating process.

13. The method of claim 1, further comprising:
forming through-electrodes penetrating the wafer substrate, prior to the forming the first conductive layer and the second conductive layer;
forming connection structures, on the first surface of the wafer substrate, overlapping the through-electrodes; and
attaching the first surface of the wafer substrate to one surface of a carrier substrate on which an adhesive layer is formed, such that the carrier substrate is on the connection structures.

14. The method of claim 13, wherein the adhesive layer has a first peel strength with respect to the wafer substrate, and
wherein the protective film has a second peel strength, greater than the first peel strength, with respect to the first portion of the first conductive layer on the edge area.

15. The method of claim 13, further comprising removing the adhesive layer and the carrier substrate after forming the protective film.

16. A method of manufacturing a semiconductor package, comprising:
preparing a wafer substrate including a first surface, a second surface opposite to the first surface, a chip area, and an edge area surrounding the chip area;
forming through-electrodes penetrating the wafer substrate;
forming, on the first surface of the wafer substrate, connection bumps connected to the through-electrodes;
sequentially forming an adhesive layer and a carrier substrate on the first surface of the wafer substrate such that the adhesive layer and the carrier substrate are on the connection bumps;
sequentially forming a first conductive layer and a second conductive layer on the second surface of the wafer substrate;
forming a photoresist pattern, including openings exposing the second conductive layer and overlapping the through-electrodes, on the second conductive layer, wherein the photoresist pattern includes a first photoresist pattern on the chip area and a second photoresist pattern on the edge area;
forming conductive patterns within the openings;
forming chip pads by removing the first photoresist pattern on the chip area from the photoresist pattern, and a first portion of the first conductive layer overlapping the first photoresist pattern and the second conductive layer;
forming dummy pads by removing the second photoresist pattern of the edge area from the photoresist pattern, and a first portion of the second conductive layer overlapping the second photoresist pattern; and
forming a protective film on the second surface of the wafer substrate such that the protective film is on the chip pads and the dummy pads.

17. The method of claim 16, wherein a portion of the wafer substrate of the chip area is exposed by the forming the chip pads, and
wherein at least a second portion of the first conductive layer of the edge area is exposed by the forming the dummy pads.

18. The method of claim 16, wherein the dummy pads are on a second portion of the second conductive layer on the edge area.

19. A method of manufacturing a semiconductor package, comprising:
providing a wafer substrate including a first surface, a second surface opposite to the first surface, a chip area, and an edge area surrounding the chip area;
forming connection structures on the first surface of the wafer substrate;
sequentially forming an adhesive layer and a carrier substrate on the first surface of the wafer substrate such that the adhesive layer and the carrier substrate are on the connection structures;
sequentially forming a first conductive layer and a second conductive layer on the second surface of the wafer substrate;
forming a photoresist pattern, including openings exposing the second conductive layer, on the second conductive layer, wherein the photoresist pattern includes a first photoresist pattern on the chip area and a second photoresist pattern on the edge area;
forming conductive patterns within the openings;
sequentially removing the first photoresist pattern on the chip area from the photoresist pattern and portions of the first conductive layer and the second conductive layer overlapping the first photoresist pattern;
sequentially removing the second photoresist pattern on the edge area from the photoresist pattern and a first portion of the second conductive layer overlapping the second photoresist pattern; and
forming a protective film on the second surface of the wafer substrate such that the protective film is on the conductive patterns,
wherein the adhesive layer has first peel strength with respect to the wafer substrate, and
wherein the protective film has second peel strength, greater than the first peel strength, with respect to a first portion of the first conductive layer on the edge area.

20. The method of claim 19, wherein the forming the photoresist pattern exposes an edge of the second conductive layer on the edge area, and
wherein the forming the conductive patterns comprises:
forming a metal film on a second portion of the second conductive layer exposed through the openings; and
forming a barrier film on the metal film by applying a voltage to an exposed edge of the second conductive layer.
